(19) United States
(12) Patent Application Publication
(10) Pub. No.: US 2026/0371476 A1
(43) Pub. Date: Nov. 19, 2026

(54) EMC Spring for Contacting a Printed Circuit Board with a Mountable Housing Part

(71) Applicant: Robert Bosch GmbH, Stuttgart (DE)

(72) Inventors: Klaus Eberle-Goubet, Rottenburg-Hailfingen (DE); Stefan Jaiser, Reutlingen (DE); Svetislav Vukovic, Stuttgart (DE)

(21) Appl. No.: 19/678,460

(22) Filed: May 15, 2026

(30) Foreign Application Priority Data
May 16, 2025 (DE) 10 2025 119 089.5

(51) Int. Cl. H05K 1/02; H05K 9/00

(52) U.S. Cl. CPC H05K 1/0216; H05K 9/0022; H05K 2201/0707; H05K 2201/10265

(57) ABSTRACT

An EMC spring for contacting a printed circuit board with a mountable housing part is disclosed. The EMC spring includes a spring element and a locking element. The EMC spring further includes at least a first contact area for contact with the printed circuit board and at least a second contact area for contact with the housing part. The spring element is configured to press the second contact area against the housing part with a spring force. The locking element is configured to lock the spring element in a biased state. The locking element is further configured to disengage the spring element from the biased state by the action of an activation force directed opposite the spring force of the biased spring element on the second contact area and to release the spring element.

This application claims priority under 35 U.S.C. § 119 to patent application no. DE 10 2025 119 089.5, filed on May 16, 2025 in Germany, the disclosure of which is incorporated herein by reference in its entirety.

The disclosure relates to an EMC spring for contacting a printed circuit board with a mountable housing part.

### BACKGROUND

Controllers, inverters, and similar electronic devices require a housing to protect sensitive electronic components from external influences such as moisture, dust, and mechanical loads while creating a safe environment, in which the electronics can operate reliably. An important aspect is sealing the housing against liquids or condensing moisture, for which so-called wet seals are used, among other things.

Wet seals are compressed during assembly so that they have a sufficient compression width on the contact surfaces, and moisture cannot penetrate into the interior of the housing. However, when using wet seals, the problem arises that the contact partner can come into undefined contact with the wet seal even before pressing, which can lead to functional limitations over the service life of the wet seal. It is possible, for example, that the seal wears more quickly or deforms under thermal stress, thereby losing effectiveness.

In order to prevent this, it is sensible to press the seal only during the last step of the housing assembly so that it remains as unstressed as possible until final pressing and ensures a permanently reliable seal.

To protect the electronics installed in the housing as well as to reduce electromagnetic radiation, the lids of the housing are shielded by one or more EMC springs. An EMC spring is a specially designed spring used in the field of electromagnetic compatibility and serves to make electrical contacts or to provide shielding to reduce undesirable interference or radiation in electronic systems.

Essentially, an EMC spring ensures that various components, such as housings, printed circuit boards, or other components, are electrically reliably connected to each other, thereby creating a defined dissipation or shielding path. In this way, electromagnetic interference signals generated, for example, by high-frequency circuits or external sources, can be selectively dissipated or shielded.

In many applications, EMC springs also play a role in sealing processes when, for example, a wet seal is compressed during final assembly while ensuring stable EMC contact.

Document DE 10 013 134 A1 describes an extendable housing consisting of a plurality of mounting frames arranged in a stack. Each mounting frame can carry at least one printed circuit board and has mechanical as well as electrical interfaces with adjacent frames. The core of the concept is a locking and unlocking device that allows for tool-free connection and release of the individual frames. Spring-loaded locking elements engage with matching pins and automatically snap into place when two mounting frames are brought together. To release, the locking elements are released via an externally accessible actuating button, whereby the frames can be pushed apart. This system allows quick assembly and disassembly of individual frame modules, even if they are in the middle of a stack, thus providing a particularly flexible and expandable housing. Since the mounting frames are typically made of die-cast metal, they offer good stability, allow for effective EMC shielding, and can be manufactured accurately.

Known solutions focus primarily on a quick, tool-free connection as well as the detachment of mounting frames via a locking and release device, but do not take into account the specific problem that a permanent, initially high spring force in EMC springs can lead to various disadvantages. For example, the known solutions do not offer any option to selectively control the timing of the increase in spring force. Thus, there is a risk that sensitive components or wet seals may be stressed by an early-acting high spring force, which may lead to deterioration of the sealing function or undesirable deformation of the contact partner. In addition, certain process steps during final assembly, for example the pressing of a wet seal, cannot be precisely coordinated with the design of the device described therein.

The disclosure is thus based on the objective of proposing a device that overcomes these disadvantages and minimizes the risk of deterioration of the sealing function and manufacturing problems.

The task is solved according to the disclosure by the subject-matter set forth below.

### SUMMARY

According to a first aspect of the disclosure, this object is achieved with an EMC spring for contacting a printed circuit board with a mountable housing part. The EMC spring comprises a spring element and a locking element, and further at least one first contact area for contact with the printed circuit board and at least one second contact area for contact with the housing part. The spring element is configured to press the second contact area against the housing part with a spring force, wherein the locking element is configured to lock the spring element in a biased state. The locking element is further configured to release the spring element from the biased state by the action of an activation force directed opposite the spring force of the biased spring element on the second contact area and to release the spring element.

The mountable housing part can in particular be a lid, a cover, or a flap of a housing for an electronic component, for example a control unit or an inverter. The type of device and the shape of the housing play a minor role in the function of the disclosure, since the disclosure relates in particular to establishing an electrical connection between a printed circuit board and a mountable housing part.

To use an EMC spring, it is positioned on the printed circuit board. At this time, the spring element is biased with the locking element. The EMC spring is connected to the printed circuit board via the first contact area. For example, the first contact area may be a pin or a screw connection with which the EMC spring is attached to the printed circuit board. When the mountable housing part, i.e., the lid, is positioned on the housing, contact is simultaneously made with the second contact area.

The second contact area can be a receptacle for the lid, in particular a contact tongue, that pushes against the mountable housing part from the inside, i.e., within the housing, when it is placed on the housing.

When the mountable housing part is placed on the housing, it is pressed against it so that a wet seal or other seal seals properly. The force applied for this is the activation force, which also acts on the EMC spring via the second contact area. The activation force activates the EMC spring by releasing the locking position of the locking element and the spring element. The spring element is released and freed from the biased state so that it presses with the spring force against the mountable housing part. An electrical connection is thus made between the printed circuit board and the mountable housing part.

As long as the spring element is in the biased state, it does not get in the way of positioning the mountable housing part. The mountable housing part may be positioned on the wet seal and then pressed down to close the housing. The EMC spring can preferably be configured to be activated even with a relatively small movement of, for example, 1 mm or 1 cm. The activation path depends on the sizing of the EMC spring, wherein small springs for small housings may have smaller activation paths and large EMC springs for large housings may have large activation paths.

The use of the locking element causes the EMC spring to have two stages and not get in the way of proper contacting of the mountable housing part. In the second stage, the released spring element ensures the electrical connection between the printed circuit board and the mountable housing part, so that overall the disadvantages of the prior art are overcome. The disclosure thus solves the problem in question.

In one embodiment, the spring element is a leaf spring or a spiral spring.

The spring element may in particular be a rigid sheet that is biased by the locking element.

In one embodiment, the locking element is a latching hook, wherein the latching hook is configured to lock the spring element in a force-fitting manner by way of the spring force of the spring element.

In this embodiment, the latching hook engages the spring element to hold it in a position biased against the spring force. The spring force of the spring element presses the spring element together with the locking element such that simple slipping, and thus a release of the spring element from the locked position, is not readily possible. Only when the activation force counteracts the spring force, and the friction force between the locking element and the spring element is reduced, is the locked position released and the spring element released. This simplifies the assembly of the housing, since the EMC spring is more resilient to interference, and the targeted activation of the spring element is improved.

In one embodiment, the spring element comprises a receptacle for receiving the latching hook.

The receptacle may improve the retention of the latching hook on the spring element by having the latching hook engage the spring element at a specially designated location. Due to the effect of the activation force, the spring element, and thus also the receptacle for the latching hook, shifts until the latching hook is ultimately released from the receptacle. When the latching hook is released from the receptacle, the spring element is free, and the spring force may act on the mountable housing part.

In one embodiment, the receptacle is a hole, in particular a punched hole, or an undercut shoulder in the spring element.

Holes, in particular punched holes, and undercut shoulders are particularly simple configurations that can be used to receive latching hooks. This is especially true for leaf springs punched out of sheet metal.

In one embodiment, the latching hook is movable and is configured to be released from the locked position of the spring element due to a gravitational force when the activation force acts on the second contact area.

Prior to activation, the latching hook is retained in position by the tension of the biased spring element. In this embodiment, the spring element moves in one direction during activation and in the other direction after activation. In this embodiment, in order for the latching hook to not be in the way during the return movement and block the spring element, the latching hook can move out of the way. This may be driven by gravitational force, i.e., falling.

In one embodiment, the latching hook comprises a latching hook spring element, wherein the latching hook is movable. The latching hook spring element is configured to move the latching hook out of the locked position when the spring element is released from the biased state.

In this embodiment, the latching hook itself can be biased so as not to be required to be in an optimal position during installation after activation. For example, the latching hook spring element may be a portion of the latching hook that, as a biased leaf spring, pushes the latching hook out of the locked position. In order to prevent the release of the spring element in this embodiment from occurring too early or unintentionally, the spring element and the latching hook support each other. The spring force of the spring element and a spring force of the latching hook spring element produce a frictional lock that is released only by the action of the activation force.

In one embodiment, the locking element is configured as a shoulder, wherein the spring element comprises a locking catch, wherein the locking catch is configured to lock into the shoulder in a force-fitting manner.

In the previous embodiments, the locking element with the latching hook has supported the spring element. In this embodiment, the spring element has a locking catch, with which it can engage the locking element in order to be locked in a biased position. In some ways, in this embodiment, the spring element supports itself against the locking element. The shoulder may be a portion of another region of the EMC spring or be integrally connected to it.

In one embodiment, the locking catch is biased toward the shoulder when the spring element is locked with the locking element.

Like the latching hook described above, the locking catch may be biased to increase the static friction between it and the locking element. If the spring element is activated by way of the action of the activation force, the locking catch is released from the shoulder. The locking catch is then moved past the shoulder due to the bias so that the spring element is released, and the spring force can push the second contact area against the mountable housing part.

In one embodiment, the locking element comprises a predetermined bending point, wherein the locking element can be changed from a locking state to a releasing state by bending at the predetermined bending point.

The predetermined bending point may in particular be configured as a one-sided predetermined bending point, so that the locking element can bend in one direction but be rigid in the other. For example, in this embodiment, the locking element may be a clip that locks a spring element formed as a spiral spring. The clip is bent to release the spring element and release it from the locked position.

In one embodiment, the locking element is configured to bend by way of the action of the activation force on the second contact point to change from the locked state to the released state.

The locking element can in particular be configured to bend due to the action of the activation force and thus release the spring element.

In one embodiment, the magnitude of the activation force is less than the spring force of the spring element.

This embodiment has the advantage that the spring element can be easily activated but, after activation, exerts a large force to connect the second contact area to the mountable housing part. This simplifies assembly without risking a good electrical connection between the printed circuit board and the mountable housing part.

In a further aspect, the disclosure relates to a printed circuit board with at least one EMC spring as described above.

It is clear that a printed circuit board may have a plurality of EMC springs to make the electrical connection to one or more mountable housing parts.

In a further aspect, the disclosure relates to the use of an EMC spring as described above for electrically connecting a printed circuit board to a mountable housing part.

In summary, the present disclosure provides an EMC spring, a printed circuit board with at least one EMC spring, and the use of an EMC spring.

The described embodiments and refinements may be combined with one another as desired.

Further possible embodiments, refinements and implementations of the disclosure also comprise combinations of features of the disclosure described previously or below with regard to the exemplary embodiments that are not explicitly mentioned.

### BRIEF DESCRIPTION OF THE DRAWINGS

The accompanying drawings are intended to provide a better understanding of the embodiments of the disclosure. They illustrate embodiments and, in connection with the description, serve to explain principles and concepts of the disclosure.

Other embodiments and many of the advantages mentioned are shown in the drawings. The illustrated elements of the drawings are not necessarily shown to scale with respect to one another.

The figures show:

FIGS. 1a - c schematically illustrate a first embodiment of an EMC spring;
FIGS. 2a - c schematically illustrate a second embodiment of an EMC spring; and
FIGS. 3a - c schematically illustrate a third embodiment of an EMC spring.

### DETAILED DESCRIPTION

In the figures of the drawings, identical reference numbers denote identical or functionally identical elements, parts or components, unless stated otherwise.

FIG. 1 schematically illustrates the activation of an EMC spring 10 according to a first embodiment. The EMC spring 10 has a spring element 12 configured as a leaf spring and a locking element 14 configured as a shoulder. The EMC spring 10 is further electrically connected to a printed circuit board 18 via a pin 16. The first contact area of the EMC spring 10 is therefore formed by the pin 16.

The EMC spring 10 has a second contact area 20 at an upper end, via which it can be connected to a mountable housing part. In FIG. 1a, the EMC spring 10 is not yet activated and biased. The EMC spring 10 of this embodiment has a locking catch 22 that engages below the locking element 14 formed as a shoulder. By locking the locking catch 22 with the locking element 14, the spring element 12 is prevented from relaxing and moving upward.

FIG. 1b shows activation of the EMC spring 10. A mountable housing part 24 is connected to the housing, wherein the housing part is moved downward with pressure so that a wet seal (not shown) properly seals the housing.

With the downward movement, the second contact area 20 engages the mountable housing part 24, thereby pushing the spring element 12 downward. The locking catch 22 slides out from under the locking element 14.

When the sealing process is complete and the pressure on the mountable housing part 24 decreases, the spring force of the spring element 12 can act and press the second contact area 20 against the mountable housing part 24. As the locking catch 22 is no longer wedged under the locking element 14, the EMC spring 10 can rise up and thus make good contact between the printed circuit board 18 and the mountable housing part 24.

FIGS. 2a - 2c show an alternative embodiment of an EMC spring 10. Also in this embodiment, the EMC spring 10 comprises a pin 16, through which electrical contact with a printed circuit board 18 is made. Furthermore, the spring element 12 is also configured as a leaf spring. In this embodiment, the locking element 14 engages in a receptacle 26 of the spring element 12 to lock the spring element 12 and bias it against its spring force.

As shown in FIG. 2b, if the mountable housing part 24 is pushed downward, the locking element 14 slides out of the receptacle 26, thereby releasing the spring element 12 from the locked position. If the pressure on the mountable housing part 24 is decreased, the second contact area 20 is pressed against the mountable housing part 24 by the spring force of the spring element 12. This is shown in FIG. 2c.

In this embodiment, the locking element 14 may be movable or at least flexible so that it is not in the way of the spring element 12 during its rising motion.

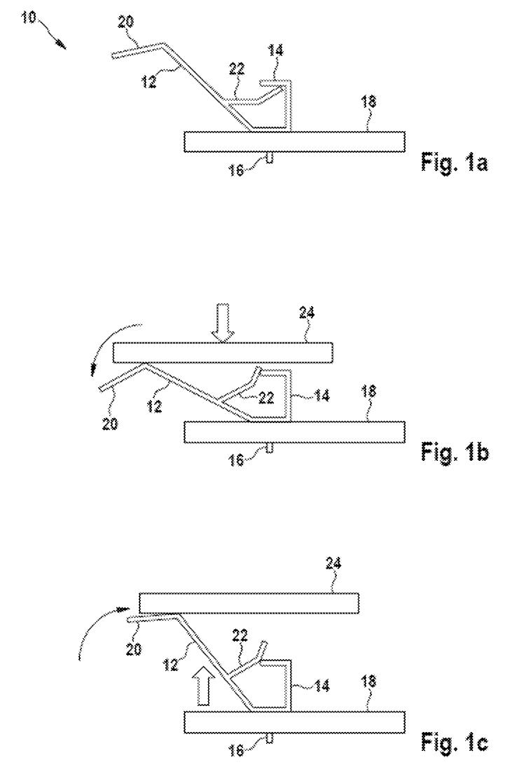

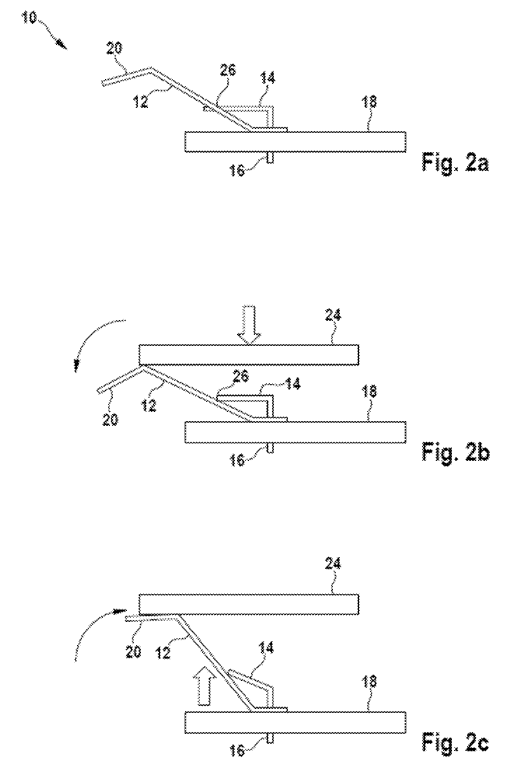

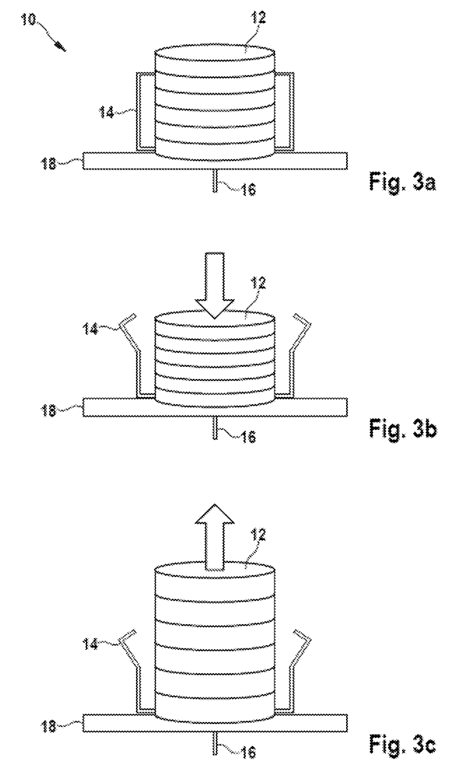

In FIGS. 3a - 3c, a third embodiment of an EMC spring 10 is shown. In this embodiment, the spring element 12 is a spiral spring that is held in place by a locking element 14 configured as clips and is thus biased.

The clips have predetermined bending points at which the clips bend due to the action of the activation force for activating the spring element 12. As a result, the spring element 12 is released and can push upward with its spring force against a mountable housing part (not shown) in this embodiment.

As with the embodiments of FIGS. 1a - c and 2a - c , the spring element 12 in FIGS. 3a - c is electrically connected to the printed circuit board 18 via a pin 16.

What is claimed is:

1. An EMC spring for contacting a printed circuit board with a mountable housing part, comprising:
a spring element;
a locking element;
at least a first contact area configured to contact the printed circuit board;
a second contact area configured to contact the housing part,
wherein the spring element is configured to press the second contact area against the housing part with a spring force,
wherein the locking element is configured to lock the spring element in a biased state, and
wherein the locking element is further configured to release the spring element from the biased state by action of an activation force directed opposite the spring force of the biased spring element on the second contact area and to release the spring element.

2. The EMC spring according to claim 1, wherein the spring element is a leaf spring or a spiral spring.

3. The EMC spring according to claim 1, wherein:
the locking element is a latching hook, and
the latching hook is configured to lock the spring element in a force-fitting manner by way of the spring force of the spring element.

4. The EMC spring according to claim 3, wherein the spring element includes a receptacle configured to receive the latching hook.

5. The EMC spring according to claim 4, wherein the receptacle is a hole or an undercut shoulder in the spring element.

6. The EMC spring according to claim 3, wherein the latching hook is movable and is configured to be released from the locked position of the spring element due to a gravitational force when the activation force acts on the second contact area.

7. The EMC spring according to claim 3, wherein:
the latching hook includes a latching hook spring element,
the latching hook is movable, and
the latching hook spring element is configured to move the latching hook out of the locked position when the spring element is released from the biased state.

8. The EMC spring according to claim 1, wherein:
the locking element is configured as a shoulder,
the spring element includes a locking catch, and
the locking catch is configured to lock into the shoulder in a force-fitting manner.

9. The EMC spring according to claim 8, wherein the locking catch is biased toward the shoulder when the spring element is locked with the locking element.

10. The EMC spring according to claim 1, wherein:
the locking element includes a predetermined bending point, and
the locking element is configured to be changed from a locking state to a releasing state by bending at the predetermined bending point.

11. The EMC spring according to claim 10, wherein the locking element is configured to bend by way of action of the activation force on the second contact point to change from the locked state to the released state.

12. The EMC spring according to claim 1, wherein the magnitude of the activation force is less than the spring force of the spring element.

13. A printed circuit board comprising at least one EMC spring according to claim 1.

14. A method comprising electrically connecting a printed circuit board to a mountable housing part with the EMC spring according to claim 1.

15. The EMC spring according to claim 5, wherein the hole is a punched hole.
